(19) United States
(12) Patent Application Publication
(10) Pub. No.: US 2026/0096375 A1
(43) Pub. Date: Apr. 2, 2026

(54) IONIZED PULSE AIR INJECTION APPARATUS, DRY CLEANING SYSTEM AND DRY CLEANING METHOD USING THE SAME

(71) Applicant: TOINTECH INC., Cheonan-si Chungcheongnam-do (KR)

(72) Inventor: Dong Seok OH, Cheongju-si Chungcheongbuk-do (KR)

(73) Assignee: TOINTECH INC., Cheonan-si Chungcheongnam-do (KR)

(21) Appl. No.: 19/219,839

(22) Filed: May 27, 2025

(30) Foreign Application Priority Data
Sep. 30, 2024 (KR) 10-2024-0132832

(51) Int. Cl. H01L 21/67; B08B 5/02

(52) U.S. Cl. CPC H10P 72/0408; B08B 5/02

(57) ABSTRACT

An ion pulse air injection apparatus includes a pressure regulator configured to regulate a pressure value of air supplied from an external source to a set pressure value, a pulse generator configured to generate a pulse for supplying the air regulated to the set pressure value in a pulse form in a set frequency band, an ion generator configured to ionize the air supplied in the pulse form from the pulse generator, and an ion pulse air injector configured to inject the ionized air in the pulse form in the ion generator onto a surface of an object.

### CROSS REFERENCE TO RELATED APPLICATION

The present application claims priority under 35 U.S.C. § 119(a) to Korean application number 10-2024-0132832, filed on Sep. 30, 2024, in the Korean Intellectual Property Office, which application is incorporated herein by reference in its entirety.

### BACKGROUND

### 1. Technical Field

Example embodiments relate to a semiconductor manufacturing system, and more particularly to an ion pulse air injection apparatus, a dry cleaning system and a dry cleaning method using the same.

### 2. Related Art

A surface cleaning process of a wafer (or semiconductor wafer and a semiconductor substrate, etc.) may be very important because a contamination of the surface of the wafer may significantly affect a productivity of a final product. This may be also true for a surface of a secondary battery film and the cleaning of product surfaces during manufacturing, as well as for a surface of displays, solar cell products, and the like, and the scope of the present disclosure may cover these areas as well.

The surface cleaning process for wafers may include a wet cleaning and a dry cleaning. The wet cleaning may have a problem that a cleaning apparatus may have a large occupying area and a waste liquid disposal may be considered. The dry cleaning may have a problem that suspended particles may not be removed properly. Specifically, there may still be a problem of recontamination of the wafer surface, as suspended particles released from the wafer surface by an injection of an air blowing may be adsorbed back onto the cleaned wafer surface.

In addition, as a plurality of internal circuits in a semiconductor device may become increasingly highly integrated and highly fined, even particles as small as about 5 μm adsorbed on the surface of the wafer may cause defects. In general, an air layer may be formed on a surface of any object. A fine air layer may also be formed on the surface of the wafer. In this case, fine particles at the level of 5 μm adsorbed on the surface of the wafer may be covered by the air layer.

As such, the fine particles covered by the air layer may not be removed by conventional dry cleaning processes such as an air blowing process. This may be because the air blowing process onto the wafer surface by blowing the air may easily not break the air layer on the wafer surface. In order to break the air layer on the wafer surface, a non-contact ultrasonic cleaning method may be used, but an internal circuit of the semiconductor device may be damaged by ultrasonic waves during the cleaning processes.

Therefore, the dry cleaning processes may be required that removes even microscopic particles covered by the air layer on the wafer surface without damaging the internal circuits of the semiconductor device.

### SUMMARY

Example embodiments provide an ion pulse air injection apparatus that may be capable of removing fine particles covered by an air layer on a wafer surface without damages an internal circuit of a semiconductor device, and a dry cleaning system and method using the ion pulse air injection apparatus.

Example embodiment also provided an ion pulse air injection apparatus that may be capable of preventing a generation of static electricity on a wafer surface due to an air friction, and a dry cleaning system and method using the same.

According to example embodiments, there may be provided an ion pulse air injection apparatus. The ion pulse air injection apparatus may include a pressure regulator, a pulse generator, an ion generator and an ion pulse air injector. The pressure regulator may regulate a pressure value of air supplied from an external source to a set pressure value. The pulse generator may generate a pulse for supplying the air regulated to the set pressure value in a form of a pulse in a set frequency band. The ion generator may ionize the air supplied in the form of the pulse from the pulse generator. The ion pulse air injector may inject the air in the form of the pulse ionized in the ion generator onto a surface of an object.

According to example embodiments, there may be provided a dry cleaning system. The dry cleaning system may include a manufacturing execution system (MES), a fault detection and classification (FDC) server and an ion pulse air injection apparatus. The MES may be configured to manage wholly a semiconductor manufacturing process. The FDC server may transmit sensor data received from semiconductor manufacturing equipment and information related to analysis results of the sensor data to the MES. When an object may be loaded into the semiconductor manufacturing equipment, the ion pulse air injection apparatus may regulate a pressure value of air supplied from an external source to a set pressure value. The ion pulse air injection apparatus may provide the air regulated to the set pressure value in a form of a discontinuous pulse in a set frequency band. The ion pulse air injection apparatus may ionize the air provided in the pulse form to inject the ionized air onto a surface of the object.

According to example embodiments, there may be provided a dry cleaning method. In the dry cleaning method, when an object may be introduced into semiconductor manufacturing equipment, a pressure value of air supplied from an external source may be regulated to a set pressure value. A pulse having a set frequency band may be generated. The air adjusted to the set pressure value may be provided in a form of a pulse. The air provided in the pulse form may be ionized. The pulse form of ionized air may then be injected onto a surface of the object.

According to example embodiments, the ionized pulse-shaped air (hereinafter, ion pulse air) may be injected onto a surface of a wafer to induce an ionic bonding with anions and cations on the wafer surface to suppress a generation of static electricity on the wafer surface due to an air friction.

Further, the air in the form of non-continuous pulses (i.e., in the form of repeated breaks and connections) may be injected onto the surface of the wafer to be cleaned to easily break an air layer formed on the surface of the wafer, thereby effectively removing even microscopic particles covered by the air layer.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 is a view illustrating a dry cleaning system in accordance with example embodiments;

FIG. 2A and FIG. 2B are views illustrating an ion pulse air injection apparatus of FIG. 1;

FIG. 3 is a view illustrating a communication between an ion pulse air injection apparatus and an FDC server in accordance with example embodiments;

FIG. 4 is a view illustrating a principle of removing static electricity on a wafer surface by ionized pulsed air injected from an ionized pulsed air injection apparatus in accordance with example embodiments; and

FIG. 5 is a flow chart illustrating a dry cleaning method in accordance with example embodiments.

### DETAILED DESCRIPTION

Embodiments of the present disclosure are hereinafter described in detail, with reference to the drawings, to facilitate practice by one of ordinary skill in the art to which the disclosure belongs. However, the present disclosure may be implemented in many different forms and is not limited to the embodiments described herein. In connection with the description of the drawings, the same or similar reference numerals may be used for the same or similar components. Further, in the drawings and associated description, descriptions of well-known features and configurations may be omitted for clarity and brevity.

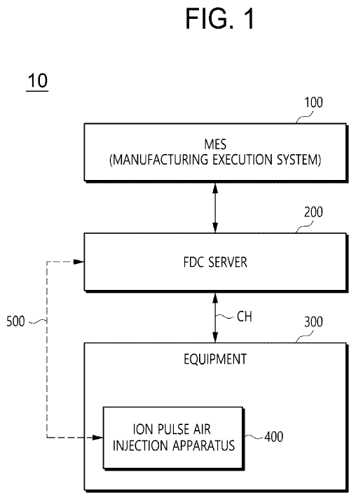

FIG. 1 is a view illustrating a dry cleaning system in accordance with example embodiments.

Referring to FIG. 1, a dry cleaning system 10 of example embodiments may include a manufacturing execution system (MES) 100, a fault detection and classification (FDC) server 200 and equipment 300. In example embodiments, the equipment 300 may include an ion pulse air injection apparatus 400.

While only one apparatus may be shown in FIG. 1, it will be apparent to those skilled in the art that a plurality of apparatuses may be provided, and where a plurality of apparatuses may be provided, each apparatus may use a separate communication channel to transmit and receive data to and from the FDC server 200.

In example embodiments, the equipment 300 may be semiconductor cleaning equipment, but is not specifically limited thereto. The equipment 300 may include any manufacturing equipment corresponding to each of a series of processes for manufacturing semiconductor device. In other words, the ion pulse air injection apparatus 400 of example embodiments may be applied to a variety of manufacturing equipment requiring removal of particles and static electricity during a process, in addition to the semiconductor cleaning equipment. For ease of description herein, the equipment 300 may be limited to the semiconductor cleaning equipment.

The MES 100 may manage the semiconductor manufacturing process. The MES 100 may also provide a user interface screen for operational commands from an operator. The MES 100 may be a management system for supporting all activities (scheduling, work ordering, quality control, work performance aggregation, etc.) for performing operations on a factory floor. In particular, the MES 100 may be a system for reducing a gap between production planning and execution. The MES 100 may perform a function to support a decision-making of an operator by providing real-time information on a status of the site. For example, the MES 100 may be configured to integrally manage all information that may be generated in a field, such as monitoring and controlling process progress information, a controlling and monitoring equipment, tracking and controlling quality information, and aggregating performance information.

The FDC server 200 may monitor and analyze sensor data measured by at least one sensor disposed in the equipment 300. For example, the FDC server 200 may receive a plurality of sensor data measured by various sensors in the equipment 300 from the equipment 300 via a communication channel (CH) using a predetermined communication method (wired or wireless). Further, the FDC server 200 may detect and identify abnormalities in the process. The FDC server 200 may categorize causes of the abnormalities, based on the analysis results of the sensor data. The FDC server 200 may also transmit various information, which may be related to the sensor data received from the equipment 300 and the analysis results of the sensor data, to the MES 100. The transmission and reception of the data between the FDC server 200 and the MES 100 and between the FDC server 200 and the equipment 300 may be performed using methods conventionally used in semiconductor manufacturing systems.

In example embodiments, the FDC server 200 may receive sensor data from the ion pulse air injection apparatus 400 installed in the equipment 300 via a wireless communication channel 500. The wireless communication channel 500 may be a communication channel may use a Bluetooth communication method, but is not particularly limited to.

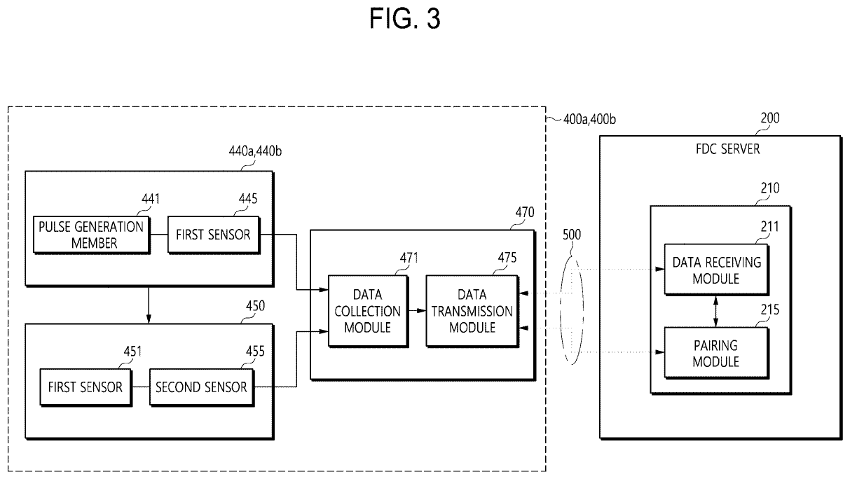

In other words, the FDC server 200 and the equipment 300 may transmit and receive the data via the communication channel CH. The ion pulse air injection apparatus 400 installed in the FDC server 200 and the equipment 300 may transmit and receive data via a separate wireless communication channel 500. To this end, the FDC server 200 may have a communicator (not shown) for communication with the equipment 300 and a communicator 210 for communication with the ion pulse air apparatus 400. In example embodiments, the communicator part 210 of the FDC server 200 may include a data receiving module 211 (FIG. 3) and a pairing module 215 (FIG. 3). The data receiving module 211 and the pairing module 215 will be described hereinafter with reference to FIG. 3.

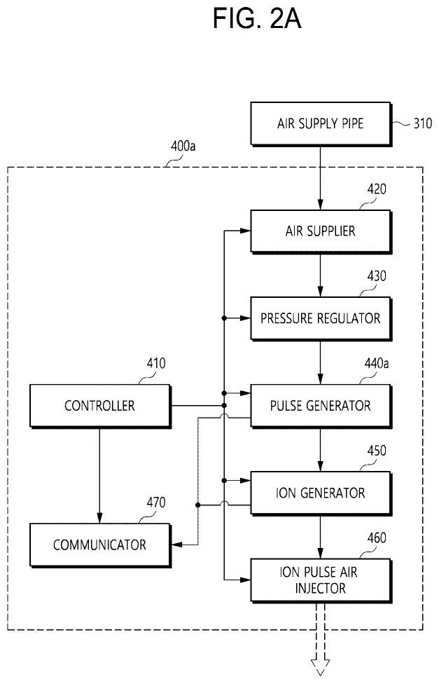

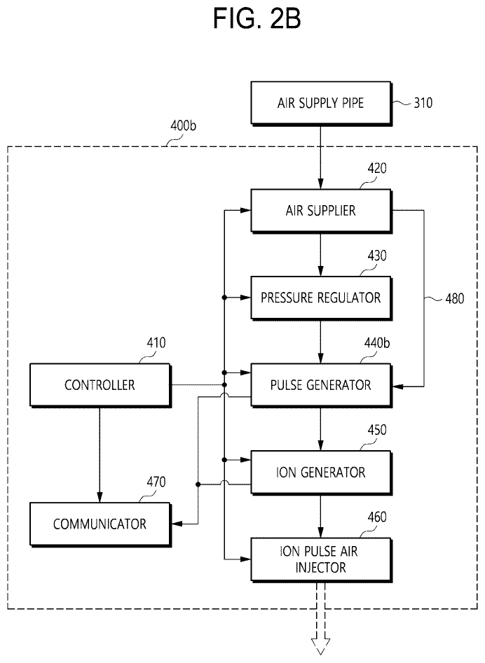

The ion pulse air injection apparatus 400 may be installed in the equipment 300. In example embodiments, the ion pulse air injection apparatus 400 may be detachably installed in the equipment 300, but is not particularly limited thereto. Further, in example embodiment, the ion pulse air injection apparatus 400 may be installed in the equipment 300 at a location where an ion pulse air injector 460 (FIG. 2A and FIG. 2B) may face a surface of the object to be cleaned (e.g., a wafer).

FIG. 2A and FIG. 2B are views illustrating the ion pulse air injection apparatus 400 of FIG. 1. An ion pulse air injection apparatus 400a of FIG. 2a and an ion pulse air injection apparatus 400b of FIG. 2b may be identical in function to configurations having the same designation, except that a pulse generator 440a and 440b may be differently operated.

Referring to FIG. 2A, the ion pulse air injection apparatus 400A may include a controller 410, an air supplier 420, a pressure regulator 430, a pulse generator 440A, an ion generator 450, an ion pulse air injector 460 and a communicator 470.

The controller 410 may control various operations of the ion pulse air injection apparatus 400a. For example, the controller 410 may control operations of each of the air supplier 420, the pressure regulator 430, the pulse generator 441a, the ion generator 450, the ion pulse air injector 460 and the communicator 470.

The air supplier 420 may, under a control of the controller 410, supply air drawn from the air supply pipe 310 installed in the equipment 300 to the pressure regulator 430. For example, one end of the air supplier 420 may be connected to the air supply pipe 310. The other end of the air supplier 420 may be connected to the pressure regulator 430. Additionally, the air supplier 420 may include, but is not particularly limited to, a solenoid valve.

For example, the air supplier 420 may, under the control of the controller 410, open a valve to supply the air from the air supply pipe 310 to the pressure regulator 430 when the object may be loaded. The air supplier may close the valve to block the air from the air supply pipe 310 from being supplied to the pressure regulator 430 when the object may be unloaded after the cleaning process may be completed.

The pressure regulator 430 may, under the control of the controller 410, adjust a pressure value of the air supplied from the air supplier 420 to a preset pressure value. The pressure regulator 430 may supply the air adjusted to the preset pressure value to a pulse generator 440a. For example, the pressure regulator 430 may adjust the pressure of the air using a regulator. In example embodiments, the set pressure value of the air may be from about 0.1 Mpa to about 0.15 Mpa, but is not particularly limited thereto.

The pulse generator 440a may be configured to generate a pulse having a preset frequency band, under the control of the controller 410, to supply the air supplied from the pressure regulator 430 to the ion generator 450 in a pulse form. For example, the pulse generator 440a may include, but is not limited to, a motorized pulse generator.

In example embodiments, the air may be supplied continuously from the air supply pipe 310 to the air supplier 420, the pressure regulator 430 and the pulse generator 440a without interruption. The air from the pulse generator 440a may be supplied to the ion generator 450 in the pulse form. Here, the air supplying in the pulse form may mean repeatedly supplying and cutting off the air. For example, if the set frequency band may be about 20 Hz, the air supplied to the ion generator 450 from the pulse generator 440a may repeat 20 interruptions and connections per second. In other words, the pulse generator 440a may supply the air to the ion generator 450 in the form of a non-continuous pulse with repeated interruptions and connections (pulsed air).

The ion generator 450 may ionize the air supplied in the pulse form from the pulse generator 440a, under the control of the controller 410. The ion generator 450 may then supply the ionized pulse form of air (ionized pulse air) to the ion pulse air injector 460. In example embodiments, the ion generator 450 may use piezoelectric components to ionize the air, but is not particularly limited thereto. For example, the ion generator 450 may ionize the air by applying a high voltage or a high current to the air supplied in pulsed form.

The ion pulse air injector 460 may, the under control of the controller 410, inject the ionized pulse air supplied from the ion generator 450 onto the surface of the object (e.g., the wafer).

The communicator 470 may, under the control of the controller 410, receive the sensor data from each of the pulse generator 440a and the ion generator 450. The communicator 470 may transmit the received sensor data to the FDC server 200 via the wireless communication channel 500 in FIG. 1. In example embodiments, the communicator 470 may include a data collection module 471 (FIG. 3) configured to collect the sensor data from a first sensor 445 (FIG. 3) of the pulse generator 440a and a second sensor 455 (FIG. 3) of the ion generator 450, as shown in FIG. 3, and a data transmission module 475 (FIG. 3) configured to transmit the collected data to the FDC server 200 via the wireless communication channel 500 in FIG. 1. The communicator 470 will be described in more detail below with reference to FIG. 3.

The ion pulse air injection apparatus 400b shown in FIG. 2B may include a pulse generator 440b configured to generate a pulse in a different manner than the pulse generator 440a of FIG. 2A, as described above. For example, the pulse generator 440a of FIG. 2A may generate the pulse using the motorized pulse generator. In contrast, the pulse generator 440b of FIG. 2B may generate the pulse using a pneumatic pulse generator. Accordingly, the ion pulse air injection apparatus 400b of FIG. 2B may further include a working air supply line 480 configured to supply working air from an air supply 420 to the pulse generator 440b to operate the pneumatic type pulse generator of the pulse generator 440b. For example, the working air supply line 480 may include a valve for supplying and shutting off the working air. The valve may be opened and closed by the control of the controller 410.

FIG. 3 is a view illustrating a communication between the ion pulse air injection apparatuses 400a and 400b and the FDC server 200 in accordance with example embodiments.

Referring to FIG. 3, the pulse generators 440a and 440b may include a pulse generation member 441 and a first sensor 445. The ion generator 450 may include an ion generation member 451 and a second sensor 455. In example embodiments, the first sensor 445 of the pulse generators 440a and 440b may be a sensor configured to measure a pulse wavelength. Additionally, the second sensor 455 of the ion generator 450 may be a sensor configured to measure a voltage or a current.

The communicator 470 may include a data collection module 471 configured to collect the sensor data (e.g., pulse wavelength values and the voltage or the current values) measured by the first sensor 445 of the pulse generators 440a and 440b and the second sensor 455 of the ion generator 450, and a data transmission module 475 configured to transmit the collected sensor data to the FDC server 200 via the wireless communication channel 500.

Referring to FIG. 3, the FDC server 200 may include a communication member 210 configured to generate the wireless communication channel 500 for communication with the ion pulse air injection apparatuses 400a and 400b, and receive the sensor data transmitted over the wireless communication channel 500 from the communicator 470 of the ion pulse air injection apparatuses 400a and 400b.

The communication member 210 of the FDC server 200 may include a data receiving module 211 and a pairing module 215.

The data receiving module 211 may receive the sensor data transmitted from the data transmission module 475 of the ion pulse air injection apparatuses 400a and 400b. Further, the pairing module 215 may pair the data transmission module 475 of the ion pulse air injection apparatuses 400a and 400b with the data receiving module 211 of the FDC server 200 to generate the wireless communication channel 500. For example, the wireless communication channel 500 may be, but is not limited to, a Bluetooth communication.

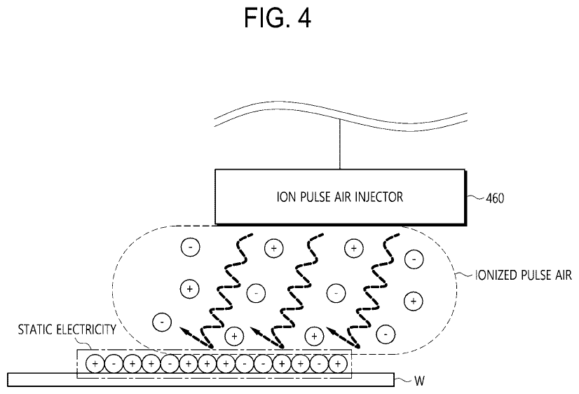

FIG. 4 is a view illustrating a principle by which static electricity on a wafer surface is eliminated by ionized pulse air injected from an ionized pulse air injection apparatus 400 in FIG. 1 in accordance with example embodiments.

During a process of blowing the air to clean the surface of wafer W, the static electricity may be generated on the surface of wafer W due to a friction between the continuously supplied air and the surface of wafer W. The static electricity generated on the surface of the wafer W may cause various problems. For example, the particles suspended by electrostatic attraction may be adsorbed on the surface of wafer W, or internal circuits may be affected as the static electricity discharges through the internal circuits formed on wafer W. In addition, the electromagnetic waves that accompany the discharge of static electricity may cause semiconductor manufacturing equipment to malfunction.

The ion pulse air injection apparatus 400 (FIG. 1) of example embodiments may inject the ionized pulse-shaped air (i.e., ion pulse air) onto the surface of the wafer W, as shown in FIG. 4, so that the anions and the cations present on the surface of the wafer W may be ionically bonded with the cations and the anions contained in the ion pulse air, respectively. Accordingly, the generation of static electricity on the surface of the wafer W may be suppressed.

Further, by blowing the air in the form of the non-continuous pulse (i.e., the pulse repeatedly interrupted and connected) on the surface of the wafer W to be cleaned, the air layer on the surface of the wafer W may be easily broken, thereby improving the removal rate of fine particles covered by the air layer.

In example embodiments, the particles, which may be separated and suspended from the surface of the wafer W by the ionized pulse air injected from the ionized pulse air injector 460, may be collected by an exhaust apparatus (not shown) installed in the equipment 300.

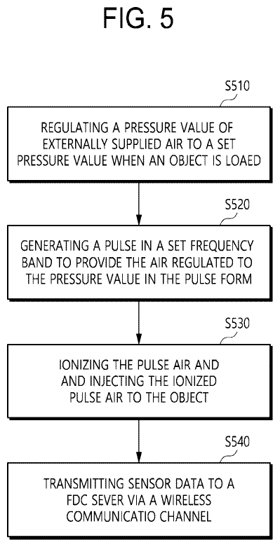

FIG. 5 is a flow chart illustrating a dry cleaning method in accordance with example embodiments. In describing the dry cleaning method of example embodiments with reference to FIG. 5, reference may be made to at least one of the drawings of FIG. 1 to FIG. 4.

At S510, the ion pulse air injection apparatus 400 (FIG. 1) may control the air supplier 420 to supply the air from the air supply pipe 310 installed in the equipment 300 (FIG. 1) to the pressure regulator 430 when the wafer W to be cleaned (W, FIG. 4) may be loaded into the equipment 300 (FIG. 1). Further, the ion pulse air injection apparatus 400 in FIG. 1 may control the pressure regulator 430 to adjust the pressure value of the air supplied from the air supplier 420 to reach the preset pressure value, and supply the air adjusted to the preset pressure value to the pulse generators 440a and 440b in FIG. 2A and FIG. 2B.

At S520, the ion pulse air injection apparatus 400 in FIG. 1 may control the pulse generators 440a and 440b in FIG. 2A and FIG. 2B to generate the pulse having the preset frequency band, and supply the air adjusted to a set pressure value to the ion generator 450 in the form of the generated pulses.

At S530, the ion pulse air injection apparatus 400 in FIG. 1 may control the ion generator 450 to ionize the air supplied in the form of pulses from the pulse generators 440a and 440b, and supply the ionized pulse-shaped air (ion pulse air) to the ion pulse air injector 460. Further, the ion pulse air injection apparatus 400 in FIG. 1 may control the ion pulse air injector 460 to inject the ionized pulse air onto the surface of the wafer W to be cleaned.

At S540, the ion pulse air injection apparatus 400 in FIG. 1 may control the communicator 470 to collect the pulse wavelength values measured at the pulse generators 440a and 440b and the voltage/current values measured at the ion generator 450 as the sensor data, and transmit the collected sensor data to the FDC server 200 via the wireless communication channel 500.

It is to be understood that the embodiments described above are exemplary and not limiting in all respects, as those skilled in the art to which the disclosure belongs will recognize that the disclosure may be practiced in other specific forms without altering its technical ideas or essential features. The scope of the disclosure is indicated by the following patent claims rather than by the detailed description above, and the meaning and scope of the claims and all modifications or variations derived from their equivalents should be construed to be included in the scope of the disclosure.

What is claimed is:

1. An ion pulse air injection apparatus comprising:
a pressure regulator configured to regulate a pressure value of an externally supplied air, and to generated a regulated air including a set pressure value;
a pulse generator configured to generate a pulse for supplying the regulated air including the set pressure value in a pulse form in a set frequency band;
an ion generator configured to ionize the air supplied in the pulse form from the pulse generator; and
an ion pulse air injector configured to inject an ionized air in the pulse form from the ion generator onto a surface of a cleaning object.

2. The ion pulse air injection apparatus of claim 1, further comprising a controller configured to control various operations of the ion pulse air injection apparatus.

3. The ion pulse air injection apparatus of claim 1, further comprising:
an air supplier connected to an air supply pipe installed in an equipment to be loaded for the cleaning object and to supply the air from the air supply pipe to the pressure regulator under a control of the controller.

4. The ion pulse air injection apparatus of claim 1,
wherein the pulse generator comprises a pulse generation member configured to generate the pulse of the set frequency band, and a first sensor configured to measure a wavelength of the generated pulse; and
wherein the ion generator comprises an ion generation member configured to ionize the air by applying a voltage or a current to the air in the pulse form, and a second sensor configured to measure the voltage or the current.

5. The ion pulse air injection apparatus of claim 4, further comprising a communicator configured to collect sensor data sensed by the first sensor and the second sensor, and transmit the collected sensor data to a Fault Detection and Classification (FDC) server via a wireless communication channel.

6. A dry cleaning system comprising:
a manufacturing execution system (MES) configured to manage a semiconductor manufacturing process;
a fault detection and classification (FDC) server configured to transmit sensor data received from a semiconductor manufacturing equipment and information related to the analysis results of the sensor data to the MES; and
an ion pulse air injection apparatus configured to regulate a pressure value of an externally supplied air to a set pressure value, to provide the regulated air including the set pressure value in a discontinuous pulse form in a set frequency band, to ionize the air provided in the discontinuous pulse form, and to spray the ionized air on a surface of a cleaning object, when the cleaning object is loaded into the semiconductor manufacturing equipment.

7. The dry cleaning system of claim 6, wherein the ion pulse air injection apparatus comprises:
a controller configured to control various operations of the ion pulse air injection apparatus;
a pressure regulator configured to regulate the pressure value of the externally supplied air;
a pulse generator configured to generate the pulse for providing the air in the form of discontinuous pulses of the set frequency band;
an ion generator configured to ionize the air by applying a voltage or a current to the air provided in the pulse form; and
an ion pulse air injector configured to inject the ionized air in the discontinuous pulse form onto the surface of the object.

8. The dry cleaning system of claim 7, wherein the ion pulse air injection apparatus is installed in the semiconductor manufacturing equipment at a location where the ion pulse air injector faces the surface of the cleaning object.

9. The dry cleaning system of claim 7, wherein the ion pulse air injection apparatus further comprises an air supplier connected to an air supply pipe installed in the semiconductor manufacturing equipment to supply the air from the air supply pipe to the pressure regulator under the control of the controller.

10. The dry cleaning system of claim 7,
wherein the pulse generator comprises a pulse generation member configured to generate the pulse, and a first sensor configured to measure a wavelength of the generated pulses; and
wherein the ion generator comprises an ion generator configured to ionize air in the discontinuous pulse form, and a second sensor configured to measure the voltage or the current.

11. The dry cleaning system of claim 10, wherein the ion pulse air injection apparatus further comprises a communicator configured to collect first and second sensor data measured by the first sensor and the second sensor, and to transmit the collected first and second sensor data to the FDC server via a wireless communication channel.

12. The dry cleaning system of claim 11, wherein the communicator comprises:
a data collection module configured to collect the first and second sensor data measured by the first sensor and the second sensor; and
a data transmission module configured to transmit the first and second sensor data collected by the data collection module to the FDC server via the wireless communication channel.

13. The dry cleaning system of claim 11, wherein FDC server comprises:
a first communication member for communication with the semiconductor manufacturing equipment; and
a second communication member for communicating with the ion pulse air injection apparatus.

14. The dry cleaning system of claim 13, wherein the second communication member comprises:
a data receiving module configured to receive the first and second sensor data transmitted from the data transmission module; and
a pairing module configured to pair the data sending module with the data receiving module.

15. The dry cleaning system of claim 11, wherein the wireless communication channel comprises a Bluetooth communication.

16. A dry cleaning method comprising:
regulating a pressure value of an externally supplied air to a set pressure value, when a cleaning object is loaded into semiconductor manufacturing equipment;
generating a pulse with a set frequency band to provide air regulated to the set pressure value in a pulse form;
ionizing the air provided in the pulse form; and
injecting the ionized air in the pulse form onto a surface of an object.

17. The dry cleaning method of claim 16, further comprising:
collecting data of a first sensor configured to measure a wavelength of the generated pulse; and
collecting data of a second sensor configured to measure a voltage or a current provided to the air.

18. The dry cleaning method of claim 17, further comprising transmitting the first and second sensor data to a fault detection and classification (FDC) server via a wireless communication channel.
